(19) United States
(12) Patent Application Publication
(10) Pub. No.: US 2026/0123328 A1
(43) Pub. Date: Apr. 30, 2026

(54) SUBSTRATE PROCESSING METHOD

(71) Applicant: TES CO., LTD, Yongin-si (KR)

(72) Inventors: Jae-Woo KIM, Yongin-si (KR); Jong-Chan LEE, Yongin-si (KR); In-Il JUNG, Yongin-si (KR); Hyeong-Wook MOON, Yongin-si (KR)

(73) Assignee: TES CO., LTD, Yongin-si (KR)

(21) Appl. No.: 19/359,630

(22) Filed: Oct. 15, 2025

(30) Foreign Application Priority Data
Oct. 24, 2024 (KR) 10-2024-0146384

(51) Int. Cl. H01L 21/67; H01J 37/32; H01L 21/3065; H01L 21/687

(52) U.S. Cl. CPC H10P 72/0421; H01J 37/32449; H10P 50/242; H01J 2237/334; H10P 72/7612

(57) ABSTRACT

A substrate processing method using a chamber, which is provided with an upper showerhead, a substrate support, and a lower showerhead assembly, is disclosed. The substrate processing method includes: adjusting an etching amount for a lower surface and a bevel of a substrate by adjusting a substrate volume ratio and a substrate gas ratio; providing plasma while supplying an etching gas toward the lower surface of the substrate; and supplying purge gas above the substrate.

### CROSS-REFERENCE TO RELATED APPLICATIONS

A claim for priority under 35 U.S.C. § 119 is made to Korean Patent Application No. 10-2024-0146384 filed on Oct. 24, 2024, in the Korean Intellectual Property Office, the entire contents of which are hereby incorporated by reference.

### BACKGROUND OF THE INVENTION

### Field of the Invention

The present invention relates to a substrate processing method, and more particularly to the substrate processing method capable of etching a lower surface of a substrate or the lower surface and a bevel of a substrate in a single process.

### Description of the Related Art

Generally, when various patterns are formed on a top surface or an upper surface of a substrate, a thin film can be deposited on a lower surface or a bottom surface of the substrate to prevent damage to the substrate and compensate for substrate deflection. Such a thin film deposited on the lower or bottom surface of the substrate can be removed during the process through etching or similar steps.

However, when the thin film is deposited on the lower or bottom surface of the substrate, this thin film can also be deposited on a bevel of the substrate in addition to the lower or bottom surface. Thus, it is required to remove the thin film deposited on the bevel of the substrate as well.

In apparatuses based on conventional art, either separate equipment is provided to remove the thin film from the bottom or lower surface and the bevel of the substrate, or separate processes are used to remove the bottom or lower surface and the bevel of the substrate. This requires a large installation area for the equipment and, furthermore, the etching process consumes significant time and cost.

### SUMMARY OF THE INVENTION

The present invention is contemplated to solve problems in the prior art mentioned above. Thus, it is an object of the present invention to provide a substrate processing method capable of etching a lower surface of a substrate or the lower surface and a bevel of the substrate by a single process.

To achieve the above object, the present invention may provide a substrate processing method using a chamber, which is provided with an upper showerhead configured to supply purge gas above a substrate, a substrate support configured to support a lower surface of an edge of the substrate, and a lower showerhead assembly configured to supply etching gas toward a lower surface of the substrate, the method comprising: adjusting an etching amount for the lower surface and a bevel of the substrate by adjusting a substrate volume ratio and a substrate gas ratio; providing plasma while supplying the etching gas toward the lower surface of the substrate; and supplying the purge gas above the substrate, wherein the substrate volume ratio corresponds to a ratio of an upper volume located above the substrate in an interior of the chamber to a lower volume located below the substrate and surrounded by the substrate support and the lower showerhead assembly, and the substrate gas ratio corresponds to a ratio of a purge gas amount supplied above the substrate to an etching gas amount supplied through the lower showerhead assembly.

The adjusting of the etching amount may include etching only the lower surface of the substrate by adjusting the substrate gas ratio to be equal to or greater than the substrate volume ratio.

Further, the adjusting of the etching amount may include etching the lower surface and the bevel of the substrate by adjusting the substrate gas ratio to be less than the substrate volume ratio.

Meanwhile, the chamber may be further provided with an additional supply line for supplying the purge gas above the edge of the substrate, and when the substrate gas ratio is adjusted, an amount of the purge gas supplied through the upper showerhead or through the upper showerhead and the additional supply line may be adjusted.

Further, when the substrate volume ratio is adjusted, a distance between the upper showerhead and the substrate may be adjusted.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is a flowchart illustrating a substrate processing method according to one embodiment of the present invention; and

FIGS. 3A and 3B are diagrams illustrating results of etching a bevel of a substrate by the substrate processing method of the present invention.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to an embodiment of the present invention will be described with reference to drawings, and then a substrate processing method will be described.

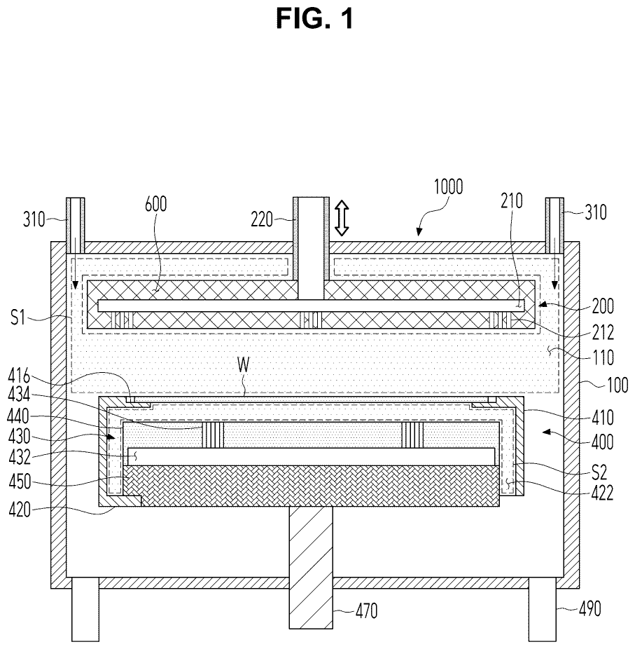

FIG. 1 is a side sectional view of a substrate processing apparatus 1000 according to one embodiment of the present invention.

Referring now to FIG. 1, the substrate processing apparatus 1000 may include a chamber 100 providing a processing space 110 for a substrate W, an upper showerhead 200 provided at an upper region of an interior of the chamber 100 to supply purge gas or the like toward an upper surface or a top surface of the substrate W, a substrate support 400 provided at an lower region of the interior of the chamber 100 to support a lower surface or a bottom surface of an edge of the substrate W, and a lower showerhead assembly 430 provided at an interior of the substrate support 400 to supply process gas, such as etching gas, toward a lower surface or a bottom surface of the substrate W.

The substrate processing apparatus 1000 may be equipped with a chamber 100 providing the processing space 110 therein.

The chamber 100 may provide the processing space 110 in which a deposition process for the substrate W is performed, in the interior thereof.

An upper region of the interior of the chamber 100 may be provided with the upper showerhead 200 for supplying the purge gas or the like which comprises inert gas towards the upper or top surface of the substrate W. Hereinafter, the upper surface of the substrate W also indicates the top surface thereof, and likewise, the lower surface of the substrate W also indicates the bottom surface thereof. Such indication may be applied to components of the substrate processing apparatus 100, in addition to the substrate W.

The upper showerhead 200 may be provided with a heater (not shown) in an interior thereof, and may be configured to be movable in up and down directions at an upper portion of the chamber 100. The upper showerhead 200 may be provided with a plurality of upper through holes 212.

At the upper portion of the chamber 100, an upper supply line 220 to which the inert gas or the like is supplied, may be connected. The inert gas supplied along the upper supply line 220 may be supplied through the upper diffuser 210, and then through the upper showerhead 200, to the upper surface of the substrate W.

Further, the upper showerhead 200 may be connected to a RF power supply 600 to be supplied with RF power. That is, the upper showerhead 200 may serve as an upper electrode.

Meanwhile, an additional supply line 310 for supplying the purge gas comprising the inert gas or the like, may be further provided to an upper edge of the chamber 100. The purge gas supplied via the additional supply line 310 may be supplied towards the edge of the substrate W above the substrate W.

By further supplying the purge gas via the additional supply line 310, the supplied purge gas may form a downward airflow in the interior of the chamber 100 along with the purge gas supplied via the upper showerhead 200. Thereby, the process gas supplied toward the lower surface of the substrate W may not be introduced to the upper surface of the substrate W, but instead may be moved to the lower region of the interior of the chamber 100.

The purge gas supplied via the additional supply line 310 may be the same as the purge gas supplied via the upper supply line 220, or may comprise different types of inert gas.

Meanwhile, the lower region of the interior of the chamber 100 may be provided with the substrate support 400 on which the substrate W is seated and supported.

The substrate support 400 may be configured to be movable in the up and down directions in a lower region of the processing space 110, or may be configured as a fixed type. The substrate support 400 may support the edge of the lower surface of the substrate W, and may be provided with a support bar 470 extending downwardly.

The substrate support 400 may include a substrate holder 410 that supports the lower surface of the edge of the substrate W, and a lower showerhead assembly 430 provided in an interior of the substrate holder 410 to supply the process gas, such as the etching gas, toward the lower surface of the substrate W.

The substrate holder 410 may support the lower surface of the edge of the substrate W. For example, an upper portion of the substrate holder 410 may be open, and a recess 416 may be formed along an edge of the open upper portion of the substrate holder 410. The substrate W may be seated or rested in the recess 416, and the edge of the lower surface of the substrate W may be supported by the recess 416. That is, the edge of the lower surface of the substrate W may be annularly supported by the recess 416. However, although not shown in the drawings, it is also possible to support the edge of the lower surface of the substrate W by other mechanisms such as a lift pin.

Meanwhile, the lower showerhead assembly 430 may be provided within the interior of the substrate holder 410.

The lower showerhead assembly 430 may include, for example, a lower showerhead plate 440 having a plurality of lower through holes 434 formed therein, and a lower plate 450 supporting the lower showerhead plate 440.

The process gas is via through a lower supply line (not shown) which passes through the drive bar 470, and the process gas supplied along the lower supply line (not shown) is supplied to the lower showerhead plate 440 through a lower diffuser 432. The process gas supplied to the lower showerhead plate 440 may be supplied to the lower surface of the substrate W through the lower through hole 434.

In this case, the lower showerhead assembly 430 may be grounded to generate plasma between the substrate W and the assembly 430.

Meanwhile, a heat exchange path (not shown) may be formed in the lower plate 450, and a heat exchange fluid or the like may flow along the heat exchange path to adjust a temperature of the process gas or a temperature inside the chamber 100 via heat exchange.

Further, the lower plate 450 may serve to support the lower showerhead plate 440 and the substrate holder 410.

In this case, the lower showerhead plate 440 may be connected to an upper surface or a top surface of the lower plate 450.

Additionally, a fixing member 420 supporting a lower end portion of the substrate holder 410, may be connected to the lower plate 450.

At this point, the fixing member 420 does not completely seal and couple the lower end portion of the substrate holder 410 and the lower plate 450, and a plurality of fixing members 420 may be provided and spaced apart at predetermined intervals along an outer circumference of the lower plate 450.

In other words, when the plurality of fixing members 420 are provided, spaces between neighboring fixing members 420 may be open downward to communicate with the interior of the chamber 100. Thus, a space between side surfaces of the lower showerhead plate 440 and the lower plate 450 and the inner opposite surface of the substrate holder 410 may form an exhaust path 422.

In this case, the process gas supplied from the lower showerhead assembly 430 may be exhausted through the exhaust path 422 to the lower region of the interior of the chamber 100, and may be exhausted to an exterior of the chamber 100 through an exhaust outlet 490 provided at the lower portion of the chamber 100.

In the substrate processing apparatus 1000 having the configuration described above, the process gas such as the etching gas or the like may be supplied from the lower showerhead assembly 430 toward the lower surface of the substrate W, and the plasma may be generated by such process gas.

For example, if a thin film deposited on the lower surface of the substrate W is to be removed, the process gas for etching may be supplied from the lower showerhead assembly 430, and the process gas may be activated by the plasma and remove the thin film on the lower surface of the substrate W.

However, when the thin film is deposited on the lower surface of the substrate W to prevent damage to the substrate W, such a thin film may be deposited on a bevel in addition to the lower surface of the substrate W.

In apparatuses according to conventional art, separate equipment is provided to remove the thin films from the lower surface and the bevel of the substrate W, and thus separate process is used to remove the thin film from the bottom surface and the bevel of the substrate W. These separate equipment and process consume significant time and cost.

The present invention is implemented to provide a substrate processing method in which the thin film on the lower surface and the thin film on the bevel in the substrate W are not removed by the separate equipment or process, but can be removed by a single process.

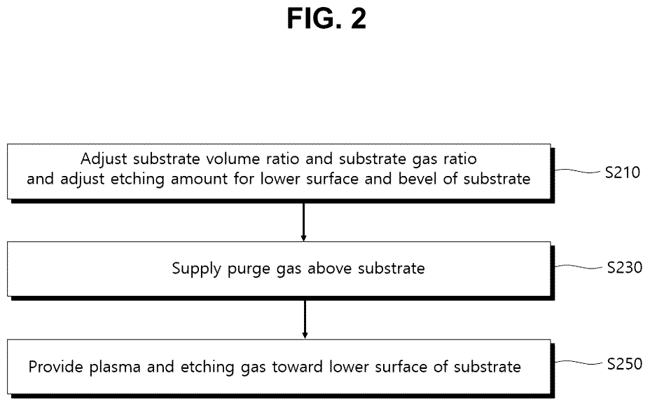

FIG. 2 is a flowchart illustrating the substrate processing method according to one embodiment of the present invention.

Referring to FIG. 1 and FIG. 2, the substrate processing method may include a step of adjusting an etching amount for the lower surface and the bevel of the substrate W by adjusting a substrate volume ratio and a substrate gas ratio (S210), a step of supplying the purge gas from above the substrate W (S230), and a step of providing the plasma while supplying the etching gas toward the lower surface of the substrate W (S250).

Here, the step of supplying the purge gas and the step of providing the plasma are described in a separate order for convenience, and are not limited thereto. For example, the step of supplying the purge gas and the step of providing the plasma may be performed simultaneously, or the step of providing the plasma may be performed first and then the step of supplying the purge gas may be performed.

First, by adjusting the substrate volume ratio and the substrate gas ratio, the amount of etching on the lower surface and the bevel of the substrate W may be adjusted (S210).

According to the inventor's research, it has been confirmed that the substrate volume ratio and the substrate gas ratio are very crucial when the etching is to be performed on the lower surface and the bevel of the substrate W by supplying the etching gas toward the lower surface of the substrate W.

Here, the substrate volume ratio corresponds to a ratio S1/S2 of an upper volume S1 located above the substrate W inside, i.e., in the interior of the chamber 100 to a lower volume S2 located below the substrate W and surrounded by the substrate support 400 and the lower showerhead assembly 430.

Further, the substrate gas ratio corresponds to a ratio (purge gas volume/etching gas volume) of a purge gas volume (or amount) (sccm (standard cubic centimeters per minute)) supplied from above the substrate W to an etching gas volume (or amount) (sccm) supplied through the lower showerhead assembly 430.

The following [Table 1] shows experimental results of the inventor, and indicates the etching amounts of the lower surface and bevel of the substrate W according to the substrate volume ratio and substrate gas ratio.

TABLE 1

| | Substrate | Substrate | Etching amount | Etching amount |
|---|---|---|---|---|
| | gas | volume | of bevel of | of lower surface |
| | ratios | ratio | substrate (Å) | of substrate (Å) |
| Example 1 | 2.0 | 2.0 | 0.7 | 715 |
| Example 2 | 2.0 | 2.0 | 0 | 619 |
| Example 3 | 2.0 | 2.0 | 0.9 | 849 |
| Example 4 | 2.0 | 2.0 | 0.5 | 572 |
| Example 5 | 1.3 | 2.0 | 5.5 | 711 |
| Example 6 | 0.7 | 2.0 | 24.7 | 627 |
| Example 7 | 2.0 | 2.1 | 2.0 | 657 |

Referring to [Table 1] as above, it may be appreciated that in Examples 1 to 4, the substrate gas ratio becomes equal to or greater than the substrate volume ratio, and in this case, the etching amount of the lower surface of the substrate W corresponds to 572 Å to 849 Å, so that the etching of the lower surface of the substrate W was performed smoothly.

In contrast, in Examples 1 to 4, it may be observed that the etching amount of the bevel of the substrate W corresponds to 0 to 0.9 Å, so that the etching of the bevel of the substrate W was hardly conducted.

Therefore, if the substrate gas ratio is adjusted to be equal to or greater than the substrate volume ratio in the step of adjusting the etching amount for the lower surface of the substrate W, or for the lower surface and the bevel of the substrate W, only the lower surface of the substrate W may be etched.

When the substrate gas ratio is adjusted to be equal to or greater than the substrate volume ratio, at least one of the substrate gas ratio and the substrate volume ratio may be changed.

Here, when the substrate gas ratio is adjusted, the amount of the purge gas supplied through the upper showerhead 200 or through the upper showerhead 200 and the additional supply line 310 may be varied.

Further, when the substrate volume ratio is adjusted, a distance between the upper showerhead 200 and the substrate W may be varied.

For example, by raising and lowering the upper showerhead 200 to adjust the distance between the substrate W and the upper showerhead 200, the upper volume S1 of the substrate W inside the chamber 100 may be varied.

In this case, in order to protect the upper surface of the substrate W, the distance between the substrate W and the upper showerhead 200 may be maintained equal to or less than a distance at which no plasma is generated. For example, the distance between the substrate W and the upper showerhead 200 may be maintained at 0.1 to 0.3 mm.

Thus, when the substrate volume ratio is adjusted, the distance between the substrate W and the upper showerhead 200 may be varied within a distance range in which the plasma does not occur.

Meanwhile, referring to Example 5 to Example 7 in [Table 1] above, it may be appreciated that the substrate gas ratio is less than the substrate volume ratio, and in this case, the etching amount on the lower surface of the substrate W corresponds to 627 Å to 711 Å, so that the etching on the lower surface of the substrate W was performed smoothly. Further, it may be observed that the etching amount of the bevel of the substrate W corresponds to 2.0 Å to 24.7 Å, so that the bevel of the substrate W was also actually etched.

For example, the substrate gas ratio may correspond to 0.7 to 2.0, and the substrate volume ratio may correspond to 2.0 to 2.1.

Therefore, in the step of adjusting the etching amount for the lower surface of the substrate W, or for the lower surface and the bevel of the substrate W, if the substrate gas ratio is made less than the substrate volume ratio, it becomes possible to etch the lower surface of the substrate W and the bevel of the substrate W together.

The method of adjusting the substrate gas ratio or the substrate volume ratio is similar to the method described above, so a repetitive description will be omitted.

Subsequently, the purge gas may be supplied through the upper showerhead 200 or through the upper showerhead 200 and the additional supply line 310 (S230).

Specifically, the purge gas may be supplied via the upper showerhead 200 towards the upper surface of the substrate W. Further, the purge gas may be supplied via an edge of the upper showerhead 200 (more particularly, between the inner surface of the chamber 100 and the edge of the upper showerhead 200), using the additional supply line 310.

The purge gas supplied through the upper showerhead 200 and the additional supply line 310 may comprise, but is not limited to, N₂. Further, the purge gas supplied through the upper showerhead 200 and the additional supply line 310 may comprise different types of the inert gas.

Subsequently, the etching gas may be supplied via the lower showerhead assembly 430 towards the lower surface of the substrate W (S250).

The etching gas may comprise, for example, but is not limited to CF₄, CH₂F₂, O₂, N₂, Ar or NF₃, N₂, Ar and the like.

While the etching gas is supplied toward the lower surface of the substrate W, the RF power may be supplied to the upper showerhead 200 by the RF power supply 600 and thus the plasma may be provided between the substrate W and the lower showerhead assembly 430.

Thereby, the etching may be performed on the lower surface of the substrate W, or on the lower surface and bevel of the substrate W.

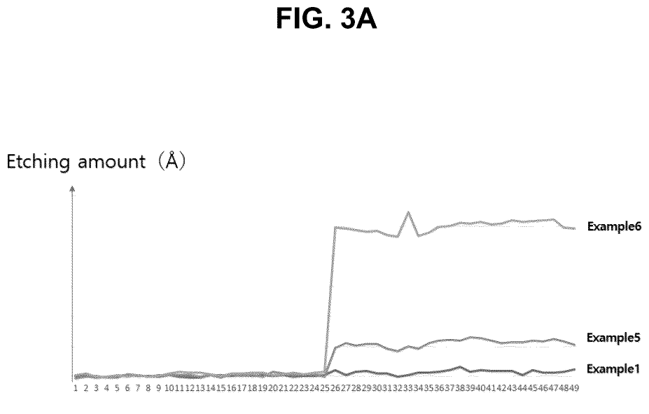

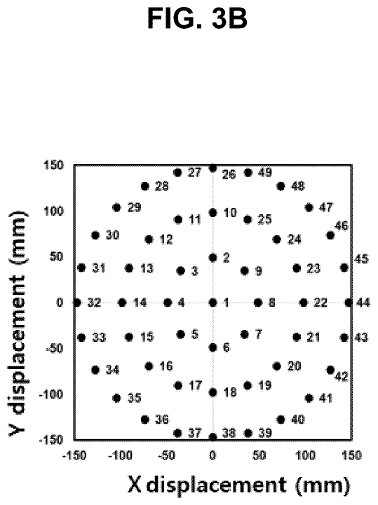

Meanwhile, FIGS. 3A and 3B are diagrams showing results of etching the substrate W by the method described above. FIG. 3A is a graph illustrating the etching result of the upper surface of the substrate W. In FIG. 3A, a vertical axis represents the etching amount of the upper surface of the substrate W, and a horizontal axis represents 49 points set on the substrate W.

FIG. 3B shows positions of the 49 points set on the substrate W. For example, point 1 may be positioned at a center of the substrate W, points 2 through 9 may be positioned on a first concentric circle surrounding point 1, points 10 through 25 may be positioned on a second concentric circle surrounding the first concentric circle, and points 26 through 49 may be positioned at edges or peripheries of the substrate W.

Referring to FIGS. 3A and 3B, it may be appreciated that in Example 1, the etching on the center of the upper surface and the bevel of the substrate W was hardly performed, as discussed above.

In the case of Example 5 and Example 6, it may be appreciated that very little etching was performed from point 1 to point 25, which means that the center of the upper surface of the substrate W was hardly etched. In contrast, it may be found that from point 26 onward, the etching amount increased, so that etching was conducted for the bevel at the edge of the substrate W.

The substrate processing method according to the present invention has the technical advantages as follows.

According to the present invention having the configuration described above, the thin film deposited on the lower surface and the bevel of the substrate can be removed by the single process with the single device without using the separate device and the separate process, and thus time and cost required for the process can be significantly reduced.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing method using a chamber, which is provided with an upper showerhead configured to supply purge gas above a substrate, a substrate support configured to support a lower surface of an edge of the substrate, and a lower showerhead assembly configured to supply etching gas toward a lower surface of the substrate, the method comprising:
adjusting an etching amount for the lower surface and a bevel of the substrate by adjusting a substrate volume ratio and a substrate gas ratio;
supplying the purge gas above the substrate; and
providing plasma while supplying the etching gas toward the lower surface of the substrate;
wherein the substrate volume ratio corresponds to a ratio of an upper volume located above the substrate in an interior of the chamber to a lower volume located below the substrate and surrounded by the substrate support and the lower showerhead assembly, and
the substrate gas ratio corresponds to a ratio of a purge gas amount supplied above the substrate to an etching gas amount supplied through the lower showerhead assembly.

2. The substrate processing method of claim 1, wherein the adjusting of the etching amount includes etching only the lower surface of the substrate by adjusting the substrate gas ratio to be equal to or greater than the substrate volume ratio.

3. The substrate processing method of claim 1, wherein the adjusting of the etching amount includes etching the lower surface and the bevel of the substrate by adjusting the substrate gas ratio to be less than the substrate volume ratio.

4. The substrate processing method of claim 2, wherein the chamber is further provided with an additional supply line for supplying the purge gas above the edge of the substrate, and
wherein when the substrate gas ratio is adjusted, an amount of the purge gas supplied through the upper showerhead or through the upper showerhead and the additional supply line is adjusted.

5. The substrate processing method of claim 2, when the substrate volume ratio is adjusted, a distance between the upper showerhead and the substrate is adjusted.

6. The substrate processing method of claim 3, wherein the chamber is further provided with an additional supply line for supplying the purge gas above the edge of the substrate, and
wherein when the substrate gas ratio is adjusted, an amount of the purge gas supplied through the upper showerhead or through the upper showerhead and the additional supply line is adjusted.

7. The substrate processing method of claim 3, when the substrate volume ratio is adjusted, a distance between the upper showerhead and the substrate is adjusted.
